(19) United States
(12) Patent Application Publication
(10) Pub. No.: US 2026/0040891 A1
(43) Pub. Date: Feb. 5, 2026

(54) APPARATUS AND METHOD OF MEASURING FEATURES IN STACKED DIES

(71) Applicant: Applied Materials, Inc., Santa Clara, CA (US)

(72) Inventors: Raymond Hoiman HUNG, Palo Alto, CA (US); Yau Loong CHONG, Singapore (SG)

(21) Appl. No.: 18/789,773

(22) Filed: Jul. 31, 2024

(51) Int. Cl. H01L 21/66; H01L 21/68; H01L 25/065

(52) U.S. Cl. CPC H01L 22/12; H01L 21/681; H01L 22/34; H01L 25/0657; H01L 2225/06596

(57) ABSTRACT

A method includes bonding a second die including second feature to a first die. The first die includes a first feature. A first image of at least a portion of the first die is captured using a first image sensor disposed at a first angle that is normal to the first surface. A second image of at least a portion of the second die is captured using a second image sensor disposed at a second angle. The first and second images include at least a portion of the first feature and the second feature. At least one offset between the features are determined based on the first image and the second image. An alignment correction between the dies are determined based on the offset. One or more alignment commands are sent based on the alignment correction to a robot end effector system of an optical inspection system.

### BACKGROUND

### Field

Embodiments of the present invention generally relate to a method and apparatus for forming an aligned 3D integrated circuit (3D IC).

### Description of the Related Art

Electronic devices, such as tablets, computers, copiers, digital cameras, smart phones, control systems, and automated teller machines, among others, often include integrated circuit die(s) for some desired functionality. A three-dimensional (3D) device package is a type of microelectronics device packaging structure that integrates multiple fabricated dies into a single stacked compact package. This approach allows designers to create more complex and powerful systems by integrating different components that have improved power consumption levels and performance.

A 3D device package can include a three-dimensional integrated circuit (3D IC), which is an integrated circuit fabricated by stacking at least two or more 2D ICs (e.g., die) vertically using, for example, through silicon vias (TSVs), or copper-copper (Cu—Cu) connections. Stated differently multiple dies may be stacked vertically on one another so that they behave as a single device to achieve device performance improvements at a reduced power and footprint (size).

In order for the 3D IC in a 3D device package to operate correctly, the patterned layers of the at least two or more ICs (or die) must be aligned. Misalignment between the 2D ICs may cause short circuits, connection failures, or the like. As the 2D ICs increase in complexity while decreasing in size, alignment of the stacked dies becomes more important and much more complex.

Therefore, there is a need for an apparatus and method of reliably stacking two or more ICs or die that solves the problems described above.

### SUMMARY

According to one or more embodiments, a method for forming a device, includes bonding a second die, which has a second feature formed on a first surface of the second die, to a first die, wherein the first die having a first feature formed on a first surface of the first die, capturing a first image of at least a portion of the first die using a first image sensor disposed at a first angle from a first direction that is normal to the first surface of the first die, capturing a second image of at least a portion of the second die using a second image sensor disposed at a second angle from the first direction, the first image and the second image including at least a portion of the first feature and at least a portion of the second feature, determining at least one offset between the first feature and the second feature based on the first image and the second image, determining an alignment correction between the first die and the second die based on the at least one offset, and sending one or more alignment commands based on the determined alignment correction to a robot end effector system of an optical inspection system.

According to one or more embodiments, an optical inspection system includes an imaging device, the imaging device including a first image sensor disposed at a first angle from a first direction that is normal to a first surface of a first die of a stacked semiconductor assembly a second image sensor disposed at a second angle from the first direction, a controller coupled to the first image sensor and the second image sensor; and a memory for storing a program to be executed in the controller, the program comprising instructions when executed cause the controller to: capture a first image of the device using the first image sensor, the device comprising a second die bonded to a first die that is bonded to a base substrate, the first die having a first feature formed on a first surface of the first die and the second die having a second feature formed on a first surface of the second die, capture a second image of the device using the second image sensor, the first image and the second image including at least a portion of the first feature and at least a portion of the second feature, determine at least one offset between the first feature and the second feature based on the first image and the second image, determine an alignment correction between the first die and the second die based on the at least one offset, and send one or more alignment commands based on the alignment correction to a robot end effector system of the optical inspection system for use in forming a subsequent device.

According to one or more embodiments, an imaging device includes a first image sensor disposed at a first angle from a first direction that is normal to a first surface of a first die of a stacked semiconductor assembly, a second image sensor disposed at a second angle from the first direction, a controller coupled to the first image sensor and the second image sensor, and a memory for storing a program to be executed in the controller, the program comprising instructions when executed cause the controller to capture a first image of the device using the first image sensor, the device comprising a second die bonded to a first die that is bonded to a base substrate, the first die having a first feature formed on a first surface of the first die and the second die having a second feature formed on a first surface of the second die, capture a second image of the device using the second image sensor, the first image and the second image including at least a portion of the first feature and at least a portion of the second feature, determine at least one offset between the first feature and the second feature based on the first image and the second image, determine an alignment correction between the first die and the second die based on the at least one offset; and send updated alignment commands based on the alignment correction to a robot end effector system of an optical inspection system for use in forming a subsequent device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic cross-sectional view of an optical inspection system, according to one or more embodiments.

FIG. 1B is a top-down view of a portion of a die of a stacked semiconductor assembly positioned in the inspection system of FIG. 1A.

FIG. 2 is a more detailed cross-sectional view of a configuration of the optical inspection system, according to one or more embodiments.

FIG. 3 is a diagram illustrating a method for forming a stacked semiconductor assembly, according to one or more embodiments.

FIGS. 4A-4E are schematic views of a portion of a stacked semiconductor assembly during a method of forming the stacked semiconductor assembly, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

A three-dimensional integrated circuit (3D IC) is an integrated circuit fabricated by vertically stacking at least two or more two-dimensional integrated circuits (2D ICs), which are also referred to herein as die. In order for the 3D IC to operate correctly the patterned layers of interconnecting circuit elements, such as conductive pads, traces, or other similar current carrying elements, within the at least two or more 2D ICs must be aligned prior to being bonded together. Misalignment between the 2D ICs may cause short circuits, connection failures, variations in device performance or the like. In various embodiments, each of the dies include features formed on non-functional portions of each die. The non-functional portions of the die can include non-electrical circuit containing regions of the die, such as regions disposed within one or more device fabrication layers, regions positioned at the peripheral edges of the die (e.g., portions of the remaining scribe lines) or open regions formed between circuits formed within the die. Features on different dies may have the same or different cross-sectional shapes and/or critical dimensions. In the process of forming a 3D IC, the 2D ICs may be stacked and aligned based on overlay (OVL) distance measurements taken between the different features formed on the different dies determined using an optical inspection system, and/or the critical dimensions of each features.

### Example Optical Inspection System

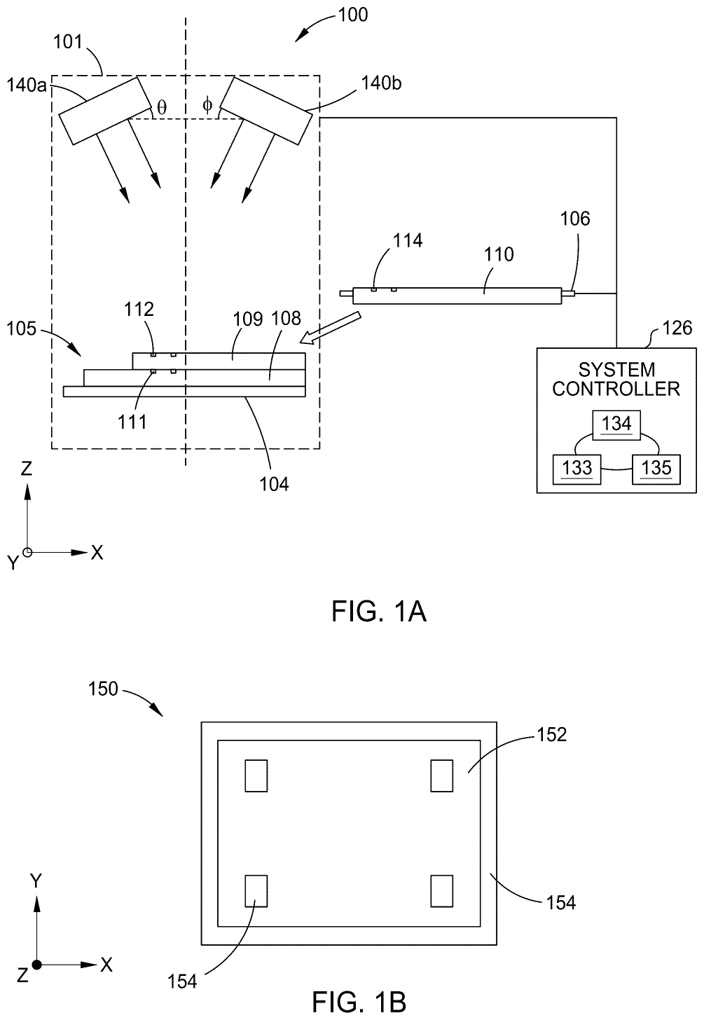

FIG. 1A is a schematic cross-sectional view of an optical inspection system 100, according to one or more examples. In various embodiments, the optical inspection system 100 may include an imaging device 101, a robot end effector system 106, and a controller 126. The imaging device 101 may include, and is not limited to, a stage 104, at least one lens (not shown), and an imaging sensor 140, and a light source (not shown). The controller 126 may be communicatively coupled to the imaging device 101 and the robot end effector system 106. The optical inspection system 100 is used to detect the location of features formed in the components within a stacked semiconductor assembly 105 and align the components of the stacked semiconductor assembly 105 (i.e., a 3D IC) based on the location of the features. The components within the stacked semiconductor assembly 105 can include a base substrate and at least one or more die, which are also referred to herein as 2D ICs.

In one example, each component (e.g., 2D IC) of the stacked semiconductor assembly 105 includes at least one feature that is configured to have a negligible effect on the operation of the stacked semiconductor assembly 105. Each of the feature(s) may be utilized by the optical inspection system 100 to align each of the components of the stacked semiconductor assembly 105. Each layer may be a 2D IC that includes functional electrical devices (herein “devices”) that are used in operation of the stacked semiconductor assembly 105. Each of the features are formed on non-functional portions of each layer. For example, the stacked semiconductor assembly 105 may be configured to include three layers: a base substrate 108, a first die 109, and a second die 110. However, the stacked semiconductor assembly 105 is not limited to three layers. For example, the stacked semiconductor assembly 105 may include two or more layers, such as the base substrate 108 and the first die 109. The base substrate 108 may include a base feature 111. The first die 109 may include a first feature 112, and the second die 110 may include a second feature 114. The base substrate 108 may be aligned to the first die 109 based on the base feature 111 and the first feature 112. The second die 110 may be aligned to the first die 109 based on the second feature 114 and the first feature 112. In one example, the base feature 111, the first feature 112, and the second feature 114 have the same size and shape. Therefore, the first die 109 may be aligned to the base substrate 108 by aligning the features, such as aligning the first feature 112 with the base feature 111. The second die 110 may be aligned with the first die 109 by aligning the first feature 112 with the second feature 114. In another example, the base feature 111, the first feature 112, and/or the second feature 114 have different shapes and/or sizes. Although only a single example of features and processes of aligning features are described herein, it is understood that other formations of features and feature alignments can be contemplated.

Each of the features within each die and within adjacent pairs of dies are positioned so that the features have a negligible effect on the operation of the devices of the stacked semiconductor assembly 105, and are used for the purposes of alignment of desirable portions of the stacked die (e.g., electrical connections formed on each die). Undesirably positioned features within a die or within adjacent die can cause electrical shorts or capacitive coupling issues as high speed electrical signals are provided through non-physically contacting adjacent circuits within the stacked semiconductor assembly 105. In one example, if the features are formed on the device side (i.e., a front side) of a die, the features are formed in non-electrical regions away from the circuits or non-electrical regions that are interleaved with the adjacent circuits so that the features do not affect the functionally of the stacked semiconductor assembly 105. In another example, the features may be formed on the backside of each die, which is opposite the device side.

In various embodiments, the controller 126 instructs the robot end effector system 106 to position the base substrate 108 onto the stage 104 based on software instructions and information stored in memory and/or received from the optical inspection system 100. The controller 126, includes a central processing unit (CPU) 133, a memory 134, and support circuits 135. The controller 126 is used to control the robot end effector system 106. The CPU is a general-purpose computer processor configured for use in an industrial setting for controlling the robot end effector system 106. The memory 134 described herein, which is generally non-volatile memory, can include random access memory, read-only memory, hard disk drive, or other suitable forms of digital storage, local or remote. The support circuits 135 are conventionally coupled to the CPU 133 and comprises cache, clock circuits, input/output subsystems, power supplied, and the like, and combinations thereof. Software instructions (program) and data can be coded and stored within the memory 134 for instructing a processor within the CPU 133.

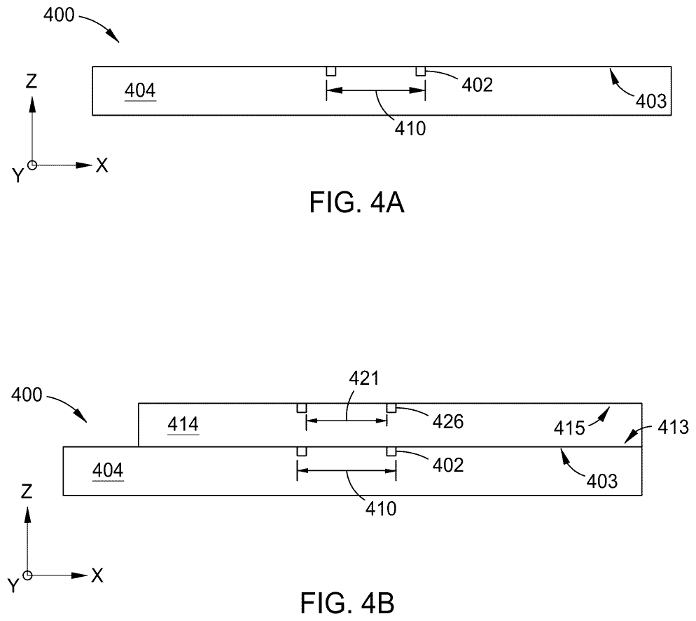

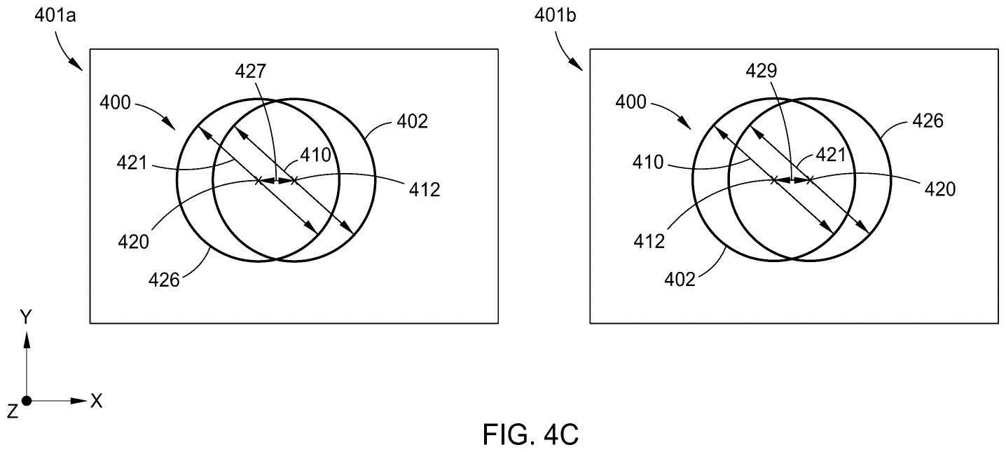

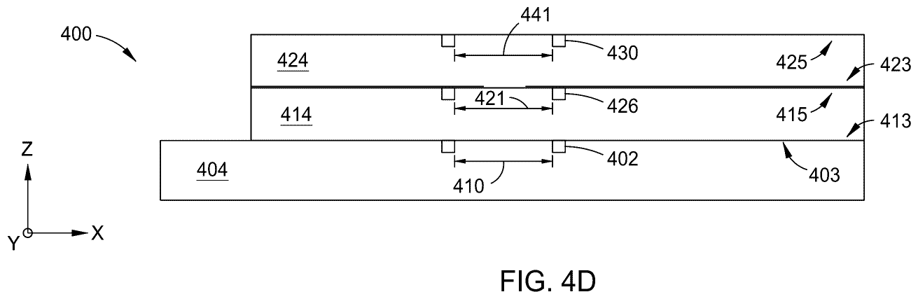

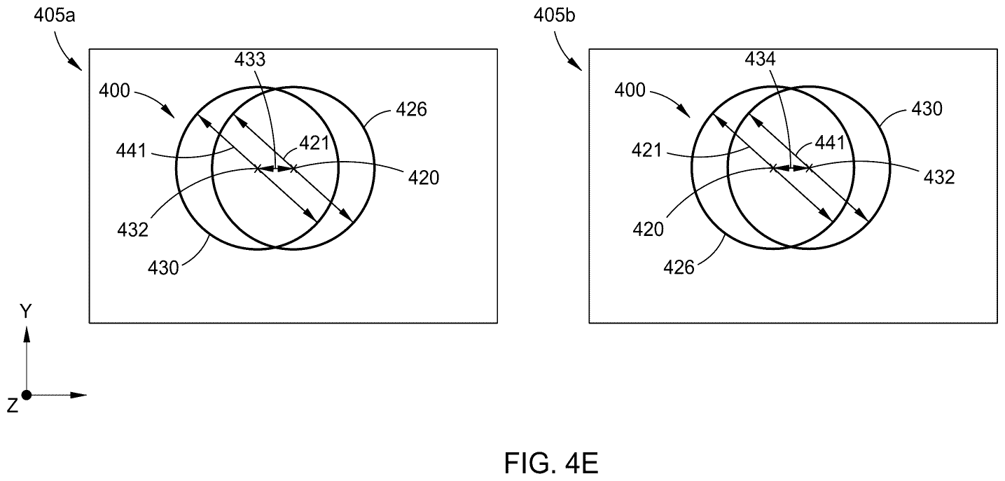

Typically, the program, which is readable by the CPU 133 in the controller 126 includes code, which, when executed by the CPU 133, performs tasks relating to the alignment of layers of the stacked semiconductor assembly 105 described herein. The program may include instructions that are used to control the various hardware and electrical components within the optical inspection system 100 to perform the various process tasks and various process sequences used to implement the methods described herein. In one example, the program includes an image processing algorithm. In one embodiment, the program includes instructions that are used to perform one or more of the operations described below in relation to FIGS. 4A-4E.

The robot end effector system 106, which can include a robot arm motion assembly, is configured to transport, stack, and then align each layer of the stacked semiconductor assembly 105 based on instructions received from the controller 126. Therefore, the robot end effector system 106 is configured to move the die of the stacked semiconductor assembly 105 along the x-axis, the y-axis, and the z-axis. Additionally, the robot end effector system 106 is configured to rotate the die of the stacked semiconductor assembly about (around), the x-axis, the y-axis, and the z-axis.

In one or more examples, the stacked semiconductor assembly 105 is formed by stacking die layer by layer. In one example, the controller 126 instructs the robot end effector system 106 to stack the first die 109 onto the base substrate 108. The first die 109 is then bonded to the base substrate 108 using a dedicated bonding tool, such as a bonder. The first die 109 may be bonded to the base substrate 108 using any suitable bonding process such as micro-bumping bonding, hybrid bonding, or the like. The controller 126 instructs the imaging device 101 to capture a first image (e.g., image 401a in FIG. 4C) of the stacked semiconductor assembly 105 from the first angle θ using the first image sensor 140a and a second image (e.g., image 401b in FIG. 4C) of the stacked semiconductor assembly 105 from the second angle ϕ using the second image sensor 140b. The first angle θ and the second angle ϕ are measured with respect a direction 117 that is normal to a surface of the stacked semiconductor assembly 105. Stated differently, the first imaging sensor 140a is positioned at a first angle θ and the second imaging sensor 140b is positioned at a second angle ϕ that are non-normal to the stacked semiconductor assembly 105. In one example, the first angle θ and the second angle ϕ are orientated in opposite directions relative to the direction 117 and have the same magnitude. In one example, the first angle θ is between 30° and 50°, and the second angle ϕ is between 30° and 500.

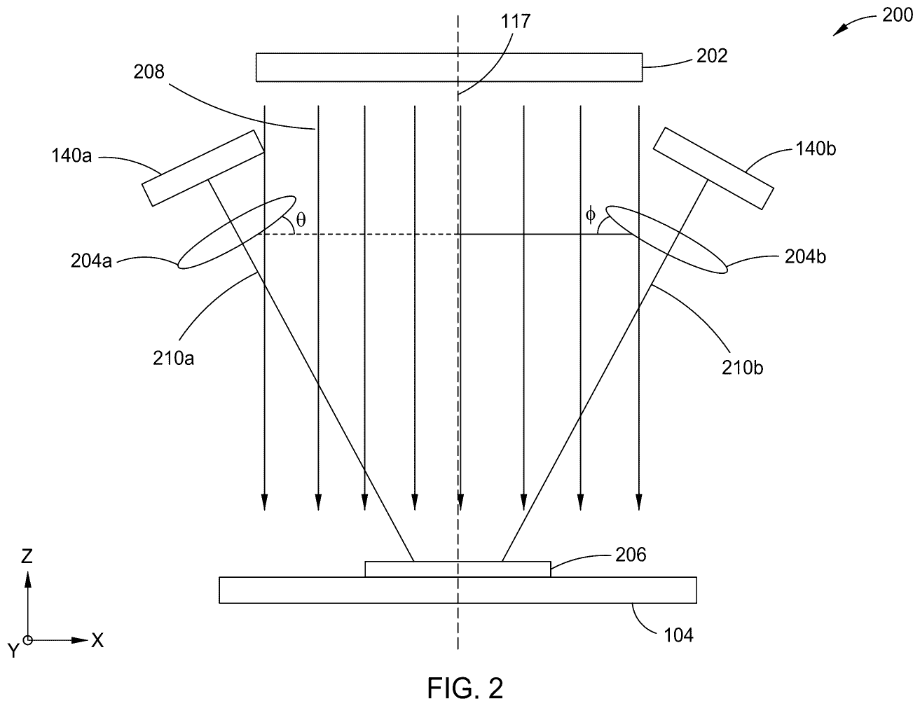

The imaging device 101 captures images of at least of a portion of the stacked semiconductor assembly 105 by delivering light towards the stacked semiconductor assembly 105 (i.e., the base substrate 108 and the first die 109) and capturing images based on the reflected light (FIG. 2). The controller 126 may determine overlay (OVL) measurements between the first feature 112 and the base feature 111 based on the image captured by the first image sensor 140a and the image captured by the second image sensor 140b using an image processing algorithm. The OVL measurements may include an offset between the first feature 112 and the base feature 111 of the stacked semiconductor device 105. Based on the offset, the controller 126 may determine and save updated alignment instructions to be used for aligning the same layers on an identical (subsequent) stacked semiconductor assembly. Additionally, based on the captured images, the controller 126 may generate a 3D reconstruction of the stacked semiconductor assembly 105. The controller 126 can generate composite images from different perspectives (views) of the 3D reconstruction. Orientation information relating to the 3-D representation can be stored in memory and used to correct the orientation and position between the first die 109 and the base substrate 108.

Based on the OVL measurements of the base feature 111 and the first feature 112, the 126 controller determines and sends commands to the robot end effector system 106 and/or stage 104 actuators for positioning and properly aligning the first die 109 onto the base substrate 108. Stated differently, the OVL measurements of the offsets between the base feature 111 and the first feature 112 and/or the information relating to the 3-D representation can used by the controller 126 to send commands to the robot end effector system 106 and/or stage 104 actuators to control a shift or a rotation in the base substrate 108, or control a shift and rotation in the first die 109 to properly align a base substrate and a first die. The desired shift and/or rotation of the base substrate 108 relative to the first die 109 can be based on previous OVL measurements made on prior similarly stacked semiconductor assemblies 105 that was stored in the memory of the controller 126. In other words, the current measurements made regarding offsets between the base feature 111 and the first feature 112, which have already been fixed by a bonding process that caused the first die to be bonded to the base substrate, can be used by the controller 126 to adjust the placement and orientation of the base feature 111 relative to the first feature 112 on subsequently formed stacked semiconductor assemblies 105 prior to bonding the components together.

The controller 126 may instruct the robot end effector system 106 to stack the second die 110 onto the first die 109. The second die 110 is bonded to the first die 109. The controller 126 instructs the first imaging sensor 140a and the second imaging sensor 140b to capture images of the stacked semiconductor assembly 105. The controller 126 may determine overlay (OVL) measurements between the first feature 112 and the second feature 114 based on the image captured by the first image sensor 140a and the image captured by the second image sensor 140b. The OVL measurements may include at least one offset between the first feature 112 and the second feature 114 of the stacked semiconductor device 105. Based on the offset, the controller may determine and save updated alignment instructions to be used for aligning the same layers on an identical (subsequent) stacked semiconductor assembly. Additionally, based on the captured images, the controller 126 may generate a 3D reconstruction of the stacked semiconductor assembly 105. The controller 126 can generate composite images from different perspectives (views) of the 3D reconstruction. Orientation information relating to the 3D representation can be stored in memory and used to correct the orientation and position between the first die 109 and the second die 110.

Based on the OVL measurements between the second feature 114 and the first feature 112, the controller 126 determines and sends commands to the robot end effector system 106 for positioning and properly aligning the second die 110 onto the first die 109 when forming a subsequent identical stacked semiconductor device in the same manner described above. This will be described in more detail below.

FIG. 1B illustrates a top-down view of a portion of a component 150 disposed within a stacked semiconductor assembly. The component 150 may correspond to any layer of a stacked semiconductor assembly, such as the stacked semiconductor assembly 105. For example, the component 150 may correspond to the base substrate 108, the first die 109, the second die 110, or any other layer of the stacked semiconductor assembly 105. As shown in FIG. 1B a front side of the component 150 (i.e., the device side) may include an electrical section 152 that includes functional IC devices and one or more non-electrical sections 154. The non-electrical sections 154 may surround the electrical sections 152, corresponding to a portion of the component 150 that is separate from the electrical sections 152, or may be interleaved with the electrical sections 152. As described above the features, such as the base feature 111, first feature 112, and second feature 114 that are used to align layers of the stacked semiconductor assembly 105, are formed within the non-electrical sections 154 in a manner such that they do not affect the functionality of the stacked semiconductor assembly 105. Therefore, the features used for alignment have negligible effect on the operation of the stacked semiconductor assembly 105, and are used for the purpose of aligning dies (layers) of the stacked semiconductor assembly 105.

FIG. 2 is a more detailed cross-sectional view of a configuration of an optical inspection system 200. In various embodiments, the optical inspection system 200 includes a light source 202, the image sensor 140a, the second image sensory 140b, and the stage 104, a first lens 204a, and a second lens 204b.

In various embodiments, input light beams 208 are provided by the light source 202 positioned above the stage 104, such as an infrared (IR) light source. The stage 104 can include optical and motion control components, such as, for example, x-direction, y-direction and rotation actuators. In another example, the stage 104 includes a mirror or other reflective component. In some embodiments, the light source 202 is configured to generate wavelengths of light that can be transmitted through a sample 206, such as the infrared wavelengths for use with samples that include die that comprise a silicon material. The light source 202 in this example provides a multi-wavelength light source that may sequentially generate different light beams each having a narrow wavelength range. In some embodiments, the multi-wavelength light source is provided by a plurality of light sources that can be activated individually. Each of the light sources generates electromagnetic radiation, and at least some of the light beams have different nominal wavelengths. In one example, the sample 206 may be the stacked semiconductor assembly 105 (FIG. 1A).

In one example, the input light beams are reflected off of the sample 206. A first portion 210a of reflected light beams are reflected towards the first lens 204a and a second portion of reflected light beams 210b are reflected towards the second lens 204b. The first lens 204a is configured to direct the focus the first portion of reflected light beams 204a towards the first image sensor 140a. The second lens is configured to focus the second portion of reflected light beams 210b towards the second image sensor 140b. Therefore, the first lens 204a is positioned at the first angle θ and the second lens is positioned at the second angle ϕ. In one example, the first lens 204a and the second lens 206b are large field lenses that have a measurement filed size (illumination area) that is slightly greater than the size of the image sensors. In another example the measurement field size of the first lens 204a and the second lens 204b are smaller than the size of the image sensors. As noted above, the first imaging sensor 140a and the second imaging sensor 140b, based on the received reflected light, can each generate an image of the sample 204, which can be used by the controller 126 (FIG. 1) to generate a 3D reconstruction of the sample 206. The 3D reconstruction of the sample may be used by the controller 126 to determine characteristics of the sample 206 such as the location and critical dimensions of features, and OVL measurements of the features. Using the determined characteristics, the controller 126 may instruct the robot end effector system 106 to position and align the components of the semiconductor assembly 105 (e.g., base substrate and/or die) of the sample 124, which will be described in more detail below.

### Layer Alignment Method

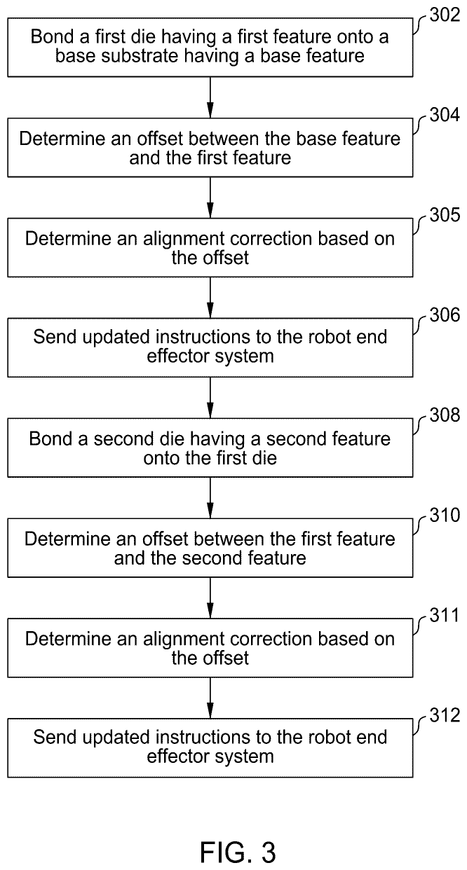

FIG. 3 is a diagram illustrating a method 300 according to one or more embodiments, for forming a stacked semiconductor assembly. The method 300 may be performed using the optical inspection system 100 described above or any other optical inspection system. Aspects of the method 300 are schematically illustrated in FIGS. 4A-4G. FIGS. 4A-4G are schematic, cross-sectional views of a portion of a stacked semiconductor assembly 400 during a method for aligning the stacked semiconductor assembly 400.

At activity 302, a first die 414 is bonded onto a base substrate 404. The base substrate 404 may be positioned and secured on a stage 104 (FIG. 1A) using the robot end effector system 106 (FIG. 1A). The first die 414 and the base substrate 404 may be bonded using any suitable bonding process such as micro-bumping bonding, hybrid bonding, or the like.

As shown in FIG. 4A, a feature 402 having a critical dimension 410 may be formed on a base substrate 404. In some embodiments, the base substrate 404 may include an interposer, bridging substrate, hybrid bonding substrate, or other similar substrate. The base substrate 404 may comprise any suitable material for forming a stacked semiconductor assembly including, but not limited to, silicon (Si), silicon dioxide (SiO₂), doped SiO₂, fused silica, quartz, silicon carbide (SiC), glass, or the like. As noted above, the feature 402 is configured to have a negligible effect on the operation of the stacked semiconductor assembly 400, and is used for the purpose of aligning subsequent dies that are to be stacked over the base substrate 404. The feature 402 may be formed on a base surface 403 of the base substrate 404. In one example, the base surface 403 may be the side of the base substrate 404 in which one or more devices or interconnect traces are formed (i.e., the front side of the base substrate 404). If the feature 402 is formed on the front side, the feature 402 may be formed on a non-electric circuit containing section 154 of the base surface 403 of the base substrate 404 away (separate) from the devices. On the other hand, the feature 402 may be formed on non-electric circuit containing sections 154 of the base substrate 504 interleaved with the die.

The feature 402 may be formed by at least the following steps: patterning the front side of the base substrate 404 to form the feature 402 within the base substrate 404 using any suitable lithography and etching method, depositing a material into the patterned feature 402 such as a metal (e.g., aluminum, titanium, tantalum, tungsten) or other useful material that provides a contrast relative to the base substrate material (e.g., silicon, glass, etc.) at the inspection wavelengths of light, and then performing a chemical mechanical planarization (CMP) on the front side of the base substrate 404 to remove any deposited material on the “field” region of the front side of the base substrate 404. The feature 402 may be formed on the front side of the base substrate 404 simultaneously with the devices or interconnects or by use of a separate process.

In other examples, the base surface 403 may be the back side of the base substrate 404. In examples in which the feature 402 is formed on the backside of the base substrate 404, the feature 402 may be formed by at least the following steps: flipping the base substrate 404, grinding the back side of the base substrate 404 down to a certain thickness, patterning the back side of the base substrate 404 to form the feature 402 using any suitable lithography and etching method, depositing a material into the feature 402 such as a metal, and then performing a chemical mechanical planarization on the back side of the base substrate 404.

The feature 402 may have any suitable cross-sectional shape that may be used for aligning layers of the stacked semiconductor assembly 400. For example, the feature 402 may have a square, rectangular, circular, plus sign shaped cross-section, or the like. The feature 402 has a critical dimension 410 that is measured relative to an alignment direction of the various components within the semiconductor assembly, such as a direction perpendicular to direction 117 and within the x-y plane (FIG. 4B).

As shown in FIG. 4B, a first die 414 may be bonded onto the base substrate 404. The first die 414 may be bonded to the base substrate 404 using any suitable bonding process such as micro-bumping bonding, hybrid bonding, or the like. The first die 414 may comprise any suitable material for forming a stacked semiconductor assembly. The first die 414 may be the same or a different material than the base substrate 404. The first die 414 includes a feature 426 formed on a first surface 415 of the first die 414. The first surface 415 being on the opposite side of the first die 414 than a second surface 413.

In one example, the first surface 415 may be the side of the first die 414 in which IC devices are formed (i.e., the front side of the first die 414). If the feature 426 is formed on the front side, the feature 426 may be formed on a non-electric circuit containing sections 154 (FIG. 1B) of the first surface 415 of the first die 414 away (separate) from the formed IC devices. On the other hand, the feature 426 may be formed on non-electric circuit containing sections 154 of the first die 414 interleaved with the devices. The feature 426 may be formed by at least the following steps: patterning the front side of the first die 414 with the feature 426 using any suitable lithography and etching method, depositing a material into the feature 426 such as a metal or other useful material that provides a contrast relative to the material from which the first die 414 is made, and then performing a chemical mechanical planarization on the front side of the first die 414. The feature 426 may be formed on the front side of the first die 414 simultaneously with the devices or using a separate process.

In another example, the first surface 415 may be the back side of the first die 414. In examples in which the feature 426 is formed on the backside of the first die 414, the feature 426 is formed by at least the following steps: flipping the first die 414, grinding the back side of first die 414 down to a certain thickness, patterning the back side of the first die 414 with the feature 426 using any suitable lithography, etching or grinding method, depositing a material into the formed feature 426 such as a metal, and then performing a chemical mechanical planarization on the back side of the first die 414.

The first die 414 and the base substrate 404 may be bonded in a manner such that the second surface 413 and the base surface 403 face (i.e., are directly adjacent to) one another.

The feature 426 may have any suitable cross-sectional shape that may be used to align the first die 414 with the base substrate 404 and with a second die 424 (FIG. 4D). For example, the feature 426 may have a square, rectangular, circular, plus sign shaped cross-section, or the like when viewed in from a perspective perpendicular to direction 117. The feature 426 and the feature 402 may have the same or different cross-sectional shapes. The feature 426 may have a critical dimension 421 that is measured relative to an alignment direction (e.g., x-y plane) of the first die 414 to the base substrate 404. Stated differently the critical dimension 421 may be measured in a direction perpendicular to direction 117. The critical dimension 421 may be equal to the critical dimension 410. In one example, the first die 414 and the base substrate 404 are properly aligned when the feature 426 is aligned with the feature 402. This will be described in more detail below.

At activity 304, at least one offset between the feature 402 and the feature 426 is determined. The at least one offset may include offsets between the feature 402 and the feature 426 along any 3D axis or plane. For example, a first offset may be determined based on a first image captured by the first image sensor 140a and a second offset may be determined based on a second image captured by the second image sensor 140b. Additionally, using each respective image captured by each image sensor allows generation of a 3-D representation of the stacked semiconductor assembly 400. In one example, the 3D reconstruction is generated by the controller 126 based on a first image captured by the first image sensor 140a and a second image captured by the second image sensor 140b. The 3D representation may illustrate the orientation and position of the first die 414 and the base substrate 404 relative to each other. Orientation information relating to the 3D representation can be stored in memory and used to correct the orientation and position of subsequently bonded die along any 3-D dimensional plane and/or axis.

As shown in FIG. 4C, the optical inspection system 100 generates a first image 401a by use of the first image sensor 140a and a second image 401b by use of the second image sensor 140b that each include a same portion of stacked semiconductor assembly 400. The first image 401a and the second image 401b are simultaneously captured by the first image sensor 140a and the second image sensor 140b, respectively. In one example, the first image 401a and the second image 401b each include at least a portion of the feature 402 and the feature 426. In one example, the feature 402 and the feature 426 have circular-cross sectional shapes as seen when viewing the features with respect to the first angle θ and the second angle ϕ that are measured with respect to direction 117 (FIG. 4B). Due to the first angle θ and the second angle ϕ, the first image 401a and the second image 401b will appear as two oval overlapping features, As shown in FIG. 4C, the feature 426 in the first image 401a and the feature 426 in the second image 401b are mirror reflections of one another due to the symmetric angled positioning of both image sensors relative to the stacked semiconductor assembly 400.

The controller 126, based on the first image 401a can determine a first offset (first OVL measurement) between the feature 402 and the feature 426 in at least one direction that is perpendicular to the direction 117 (e.g., along the x and/or the y axis) and a second offset (second OVL measurement) that is perpendicular to the direction 117 (e.g., along the x and/or the y axis) based on the second image 401b. The first offset may be a distance 427 between a center 412 of the feature 402 and a center 420 of the feature 426 in the first image 401a. Stated differently, a first OVL measurement between the feature 426 and the feature 402 may include a distance 427 measured from the center 412 of the feature 402 to the center 420 of the feature 426 in the first image 401a.

In one example, based on the distance 427, the first offset between the feature 426 and the feature 402 may include a distance in the x-direction and/or the y-direction. In one example, the distance 427 not being equal to a predetermined distance indicates a first offset in the x-y plane is present between the feature 402 and the feature 426. In one example, the predetermined distance may be determined based on a thickness of the first die and the first angle θ. Thus, the distance 427 being different from the pre-determined distance indicates a misalignment in one of or both of the x-direction and the y-direction.

The second offset may be a distance 429 between the center 412 of the feature 402 and the center 420 of the feature 426 in the second image 401b. Stated differently, a second OVL measurement between the feature 426 and the feature 402 may include a distance 429 measured from the center 412 of the feature 402 to the center 420 of the feature 426 in the second image 401b. In one example, based on the distance 429, the second offset between the feature 426 and the feature 402 may include a distance in the x-direction and/or the y-direction. In one example, the distance 429 not being equal to a predetermined distance indicates a second offset in the x-y plane is present between the feature 402 and the feature 426. In one example, the predetermined distance may be determined based on a thickness of the first die 414 and the second angle ϕ. Thus, the distance 429 being different from the pre-determined distance indicates a misalignment in one of or both of the x-direction and the y-direction.

Based on the differences between the distance 427 and the distance 429 and the pre-determined distance (i.e., the first and second offsets), the controller 126 can determine an alignment correction and transmit one or more updated alignment commands to the robot end effector system 106 based on the alignment correction when bonding a first die and a base substrate of a subsequent stacked semiconductor assembly that is identical to the stacked semiconductor assembly 400.

In another example, using computer stereo vision (i.e., the first image sensor 140a and the second image sensor 140b), the first image 401a and the second image 401b are used by the controller 126 to generate a 3D reconstruction of the stacked semiconductor assembly 400. For example, the 3D reconstruction is formed based on a comparison of pixels in the first image 401a and the second image 401b. In one example, the 3D reconstruction is generated by matching the pixels of the first image 401a with the pixels of the second image 401b and using epipolar geometry to calculate the same point in 3D space. Using the 3D reconstruction, the controller 126 may generate a composite image based on the different perspectives of the image sensors and use the composite images to determine mis-alignments between the base substrate 404 and the first die 414 in at least one of three orthogonal directions (e.g., X, Y and Z-directions). In one example, different (i.e., additional) offsets of the at least one offset between the feature 402 and the feature 426 along different axes and/or planes may be determined using different composite images from different perspectives (views) of the 3D reconstruction of the stacked semiconductor assembly 400. Advantageously, using two image sensors positioned at angles non-normal to the stacked semiconductor assembly 400 allows views of the alignment (or mis-alignment) between the feature 402 and the feature 426 from different perspectives. Therefore, the alignment between the feature 402 and the feature 426 can be viewed from multiple perspectives and misalignments in any 3D direction such as the x-direction, the y-direction, a direction within the x-y plane, a direction within the x-z plane, or the like can be detected by the controller 126. The controller 126 can determine alignment error locations and alignment error values (e.g., alignment shift, alignment rotational errors, etc.) based on the at least one offset between the features. Based on the alignment error locations and alignment error values, the controller 126 can determine an alignment correction and transmit one or more alignment commands to the robot end effector system 106 based on the alignment correction when bonding a first die and a base substrate of a subsequent stacked semiconductor assembly that is identical to the stacked semiconductor assembly 400.

At activity 305, as described above, the controller 126 determines an alignment correction between the base substrate 404 and the first die 414 based on the at least one offset. The determined alignment correction, which can include adjustments in the x, y and z directions, along with angular corrections between the bonded components (e.g., pitch, yaw or roll type corrections) can be stored in memory.

At activity 306, and as described above, based on the at least one offset, the controller 126 sends one or more alignment commands to the robot end effector system 106 based on the alignment correction for aligning a base substrate and a first die in a subsequent stack semiconductor assembly that is identical to the stacked semiconductor assembly 400.

Although examples of correcting the alignment of the stacked semiconductor assembly 400 in the x-y plane using a top-down this is for example purposes only. It is understood that any perspective of the 3D reconstruction of the stacked semiconductor assembly can be generate and used by the controller to provide updated alignment instructions to the robot end effector system 106 along any 3D axis and/or plane, such as the y axis, the y-z plane, and the like.

At activity 308, and as shown in FIG. 4D, a second die 424 is bonded onto the first die 414. The second die 424 may be positioned onto the first die 414 using the robot end effector system 106. In one example, the second die 424 may be bonded onto the first die 414 using the same bonding method used to bond the first die 414 to the base substrate 404.

The second die 424 may comprise any suitable material for forming a stacked semiconductor assembly. The second die 424 may be the same or a different material than the base substrate 404 and/or the first die 414. The second die 424 includes a feature 430 formed on a first surface 425 of the second die 424. The first surface 425 being on the opposite side of the second die 424 than a second surface 423. In one example, the feature 430 is formed in the same manner as feature 426.

In one example, the second surface 423 may be the side of the second die 424 in which devices are formed (i.e., the front side of the second die 424). The first surface 425 may be the back side of the second die 424.

In another example, the first surface 425 may be the side of the second die 424 in which devices are formed (i.e., the front side of the second die 424). The second surface 423 may be the back side of the second die 424.

The second die 424 and the first die 414 may be bonded in a manner such that the first surface 415 of the first die 414 and the second surface 423 of the second die 424 face (i.e., are directly adjacent to) one another.

The feature 430 may have any suitable cross-sectional shape that may be used to align the second die 424 with the first die 414. For example, the feature 430 may have a square, rectangular, circular, plus sign shaped cross-section, or the like as seen when viewing the features in a direction that is normal to an alignment direction (e.g., direction in the x-y plane) which is perpendicular to direction 117. In one example, the features 402, 426, and 430 have a same cross-sectional shape. In another example, the features 402, 426, and 430 have a different cross-sectional shapes. The feature 430 may have a critical dimension 421 that is measured relative to an alignment direction (e.g., x-y plane) of the second die 424 to first die 414. The critical dimension 421 may be equal to the critical dimension 441. In one example, the critical dimensions 410, 421, and 441 are equal. In another example, the critical dimensions 410, 421, and 441 are different from one another. In one example, the second die 424 and the first die 414 are properly aligned when the feature 430 is in alignment with the feature 426. This will be described in more detail below.

At activity 310, at least one offset between the feature 426 and the feature 430 is determined. The at least one offset may include offsets between the feature 426 and the feature 430 along any 3D axis or plane. For example, a third offset may be determined based on a third image captured by the first image sensor 140a and a fourth offset may be determined based on a fourth image captured by the second image sensor 140b. Additionally, using each respective image captured by each image sensor allows generation of a 3-D representation of the stacked semiconductor assembly 400. In one example, the 3D reconstruction is generated by the controller 126 based on the third image captured by the first image sensor 140a and the fourth image captured by the second image sensor 140b. The 3D representation may illustrate the orientation and position of the second die 424 and the first die 414 relative to each other. Orientation-information relating to the 3-D representation can be stored in memory and used to correct the orientation and position of subsequently bonded die along any 3-D dimensional plane and/or axis.

As shown in FIG. 4E, the optical inspection system 100 generates a third image 405a by use of the first image sensor 140a and a fourth image 405b by use of the second image sensor 140b that each include a same portion of stacked semiconductor assembly 400. The third image 405a and the fourth image 405b are simultaneously captured by the first image sensor 140a and the second image sensor 140b, respectively. In one example, the third image 405a and the fourth image 405b each include at least a portion of the feature 426 and the feature 430. In one example, the feature 426 and the feature 430 have circular-cross sectional shapes as seen when viewing the features with respect to the first angle θ and the second angle ϕ that are measured with respect to direction 117 (FIG. 4B). Due to the first angle θ and the second angle ϕ, the third image 405a and the fourth image 405b can include two oval overlapping features. As shown in FIG. 4C, the features 430 in the third image 405a and the feature 430 in the fourth image 405b are mirror reflections of one another due to the symmetric angled positioning of both image sensors relative to the stacked semiconductor assembly 400

The controller 126, based on the third image 405a can determine a third offset (third OVL measurement) between the feature 426 and the feature 430 in at least one direction that is perpendicular to the direction 117 (e.g., along the x and/or the y axis) and a fourth offset (second OVL measurement) that is perpendicular to the direction 117 (e.g., along the x and/or the y axis) based on the fourth image 405b. The third offset may be a distance 433 between a center 420 of the feature 426 and a center 432 of the feature 430 in the third image 405a. Stated differently, a third OVL measurement between the feature 426 and the feature 430 may include a distance 433 measured from the center 420 of the feature 426 to the center 432 of the feature 430 in the third image 405a.

In one example, based on the distance 433, the third offset between the feature 426 and the feature 430 may include a distance in the x-direction and/or the y-direction. In one example, the distance 433 not being equal to a predetermined distance indicates a third offset in the x-y plane is present between the feature 426 and the feature 430. In one example, the predetermined distance may be determined based on a thickness of the second die 424 and the first angle θ. Thus, the distance 433 being different from the pre-determined distance indicates a misalignment in one of or both of the x-direction and the y-direction.

The fourth offset may be a distance 434 between the center 420 of the feature 426 and the center 432 of the feature 430 in the fourth image 405b. Stated differently, a fourth OVL measurement between the feature 426 and the feature 430 may include a distance 434 measured from the center 420 of the feature 426 to the center 432 of the feature 430 in the fourth image 401b.

In one example, based on the distance 433, the fourth offset between the feature 426 and the feature 430 may include a distance in the x-direction and/or the y-direction. In one example, the distance 433 not being equal to a predetermined distance indicates a fourth offset in the x-y plane is present between the feature 426 and the feature 430. In one example, the predetermined distance may be determined based on a thickness of the second die 424 and the second angle ϕ. Thus, the distance 433 being different from the pre-determined distance indicates a misalignment in one of or both of the x-direction and the y-direction.

Based on the differences between the distance 433 and the distance 434 and the pre-determined distance (i.e., the third and fourth offsets), the controller 126 can determine an alignment correction and transmit one or more updated alignment commands to the robot end effector system 106 based on the alignment correction when bonding a second die and a first die of a subsequent stacked semiconductor assembly that is identical to the stacked semiconductor assembly 400.

In another example, using computer stereo vision (i.e., the first image sensor 140a and the second image sensor 140b), the third image 405a and the fourth image 405b are used by the controller 126 to generate a 3D reconstruction of the stacked semiconductor assembly 400. For example, the 3D reconstruction is formed based on a comparison of pixels in the third image 405a and the fourth image 405b. In one example, the 3D reconstruction is generated by matching the pixels of the third image 405a with the pixels of the fourth image 405b and using epipolar geometry to calculate the same point in 3D space. In one example, different (i.e., additional) offsets between the feature 426 and the feature 430 along different axes and/or planes may be determined using different perspectives (views) of the 3D reconstruction of the stacked semiconductor assembly 400. Advantageously, using two image sensors positioned at angles non-normal to the stacked semiconductor assembly 400 allows views of the alignment (or mis-alignment) between the feature 426 and the feature 430 from different perspectives. Therefore, the alignment between the feature 426 and the feature 430 can be viewed from multiple perspectives and misalignments in the x-direction, the y-direction, within the x-y plane, the x-z plane, and the like can be detected by the controller 126. The controller 126 can determine alignment error locations and alignment error values (e.g., alignment shift, alignment rotational errors, etc.) based on the at least one offset. Based on the alignment error locations and the alignment error values, the controller 126 can determine an alignment correction and transmit one or more alignment commands to the robot end effector system 106 based on the alignment correction for bonding a second die and a first die of a subsequent stacked semiconductor assembly that is identical to the stacked semiconductor assembly 400.

At activity 311, and as described above, the controller 126 determines an alignment correction between the first die 414 and the second die 424 based on the at least one offset. The determined alignment correction, which can include adjustments in the x, y and z directions, along with angular corrections between the bonded components (e.g., pitch, yaw or roll type corrections), can be stored in memory.

At activity 312, and as described above, based on the alignment corrections, the controller 126 sends instructions to the robot end effector system 106 for aligning a first die and a second die in a subsequent stacked semiconductor assembly that is identical to the stacked semiconductor assembly 400. This process may be repeated for each additional die used to form the stacked semiconductor assembly 400. Also, each of the at least one offsets, and alignment corrections may be determined after each die is bonded (as described above), after each die of the entire stacked semiconductor assembly 400 are bonded, or after certain quantities of dies are bonded.

Embodiments by the present principles may be implemented in hardware, firmware, software, or any combination thereof. Embodiments may also be implemented as instructions stored using one or more computer-readable media, which may be read and executed by one or more processors. A computer-readable medium may include any mechanism for storing or transmitting information in a form readable by a machine (e.g., a computing platform or a “virtual machine” running on one or more computing platforms). For example, a computer-readable medium may include any suitable form of volatile or non-volatile memory. In some embodiments, the computer-readable media may include a non-transitory computer-readable storage medium.

While the foregoing is directed to embodiments of the present principles, other and further embodiments of the principles may be devised without departing from the basic scope thereof.

What is claimed is:

1. A method for forming a device, the method comprising:
bonding a second die, which has a second feature formed on a first surface of the second die, to a first die, wherein the first die having a first feature formed on a first surface of the first die;
capturing a first image of at least a portion of the first die using a first image sensor disposed at a first angle from a first direction that is normal to the first surface of the first die;
capturing a second image of at least a portion of the second die using a second image sensor disposed at a second angle from the first direction, the first image and the second image including at least a portion of the first feature and at least a portion of the second feature;
determining at least one offset between the first feature and the second feature based on the first image and the second image;
determining an alignment correction between the first die and the second die based on the at least one offset; and
sending one or more alignment commands based on the determined alignment correction to a robot end effector system of an optical inspection system.

2. The method of claim 1, wherein the first angle and the second angle are oriented in opposite directions relative to the first direction and equal in magnitude.

3. The method of claim 1, wherein the first image sensor and the second image sensor are in communication with a controller of an optical inspection system.

4. The method of claim 1, further comprising generating a 3D reconstruction based on a comparison of pixels in the first image and the second image.

5. The method of claim 4, further comprising:
determining orientation information between the first die and the second die based on the 3D reconstruction and storing the orientation information, wherein the orientation information indicates an orientation and position between the first die and the second die.

6. The method of claim 1, wherein a cross-sectional shape of the first feature is a circle having a first critical dimension, a cross-sectional shape of the second feature is a circle having a second critical dimension, and the first critical dimension and the second critical dimension are equal.

7. The method of claim 1, wherein determining an alignment correction between the first die and the second die based on the at least one offset comprises determining an alignment correction that causes the second feature to be in alignment with the first feature in a subsequent device.

8. An optical inspection system comprising:
an imaging device, the imaging device comprising:
a first image sensor disposed at a first angle from a first direction that is normal to a first surface of a first die of a stacked semiconductor assembly;
a second image sensor disposed at a second angle from the first direction;
a controller coupled to the first image sensor and the second image sensor; and
a memory for storing a program to be executed in the controller, the program comprising instructions when executed cause the controller to:
capture a first image of the device using the first image sensor, the device comprising a second die bonded to a first die that is bonded to a base substrate, the first die having a first feature formed on a first surface of the first die and the second die having a second feature formed on a first surface of the second die;
capture a second image of the device using the second image sensor, the first image and the second image including at least a portion of the first feature and at least a portion of the second feature;
determine at least one offset between the first feature and the second feature based on the first image and the second image;
determine an alignment correction between the first die and the second die based on the at least one offset; and
send one or more alignment commands based on the alignment correction to a robot end effector system of the optical inspection system for use in forming a subsequent device.

9. The optical inspection system of claim 8, wherein the first angle and the second angle are oriented in opposite directions relative to the first direction and are equal in magnitude.

10. The optical inspection system of claim 8, wherein the instructions further comprise instructions to generate a 3D reconstruction based on a comparison of pixels in the first image and the second image.

11. The optical inspection system of claim 10, wherein the instructions further comprise instructions to determine orientation information between the first die and the second die based on the 3D reconstruction and store the orientation information in the memory, wherein the orientation information indicates an orientation and position between the first die and the second die.

12. The optical inspection system of claim 8, wherein a cross-sectional shape of the first feature is a circle having a first critical dimension, a cross-sectional shape of the second feature is a circle having a second critical dimension, and the first critical dimension and the second critical dimension are equal.

13. The optical inspection system of claim 8, wherein the instructions for determining an alignment correction between the first die and the second die based on the at least one offset further comprise instructions to determine an alignment correction that causes the second feature to be in alignment with the first feature in a subsequent device.

14. The optical inspection system of claim 8, wherein the alignment correction is determined based on a pre-determined distance between a center of the first feature and a center of the second feature.

15. An imaging device comprising:
a first image sensor disposed at a first angle from a first direction that is normal to a first surface of a first die of a stacked semiconductor assembly;
a second image sensor disposed at a second angle from the first direction;
a controller coupled to the first image sensor and the second image sensor; and
a memory for storing a program to be executed in the controller, the program comprising instructions when executed cause the controller to:
capture a first image of the device using the first image sensor, the device comprising a second die bonded to a first die that is bonded to a base substrate, the first die having a first feature formed on a first surface of the first die and the second die having a second feature formed on a first surface of the second die;
capture a second image of the device using the second image sensor, the first image and the second image including at least a portion of the first feature and at least a portion of the second feature;
determine at least one offset between the first feature and the second feature based on the first image and the second image;
determine an alignment correction between the first die and the second die based on the at least one offset; and
send updated alignment commands based on the alignment correction to a robot end effector system of an optical inspection system for use in forming a subsequent device.

16. The imaging device of claim 15, wherein the first angle and the second angle are oriented in opposite directions and equal in magnitude.

17. The imaging device of claim 15, wherein the instructions further comprise instructions to generate a 3D reconstruction based on a comparison of pixels in the first image and the second image.

18. The imaging device of claim 17, wherein the instructions to determine at least one offset between the first feature and the second feature in at least one direction perpendicular to the first direction comprise instructions to determine a difference between at least one of a distance between a center of the first feature and a center of the second feature and a predetermined distance in the first image and a distance between the center of the first feature and the center of the second feature and a predetermined distance in the second image.

19. The imaging device of claim 15, wherein a cross-sectional shape of the first feature is a circle having a first critical dimension, a cross-sectional shape of the second feature is a circle having a second critical dimension, and the first critical dimension and the second critical dimension are equal.

20. The imaging device of claim 15, wherein the alignment correction is determined based on a pre-determined distance between a center of the first feature and a center of the second feature.
